(19) United States
(12) Patent Application Publication
(10) Pub. No.: US 2024/0113517 A1
(43) Pub. Date: Apr. 4, 2024

(54) CURRENT LIMITER CIRCUIT WITH ADJUSTABLE RESPONSE TIME

(71) Applicant: Texas Instruments Incorporated, Dallas, TX (US)

(72) Inventors: Sahana Sriraj, Dallas, TX (US); Ralph Braxton Wade, III, McKinney, TX (US)

(21) Appl. No.: 17/956,343

(22) Filed: Sep. 29, 2022

(51) Int. Cl. H02H 9/02; H03K 17/687

(52) U.S. Cl. CPC H02H 9/02; H03K 17/6871

(57) ABSTRACT

A current limiter includes a gain adjustment circuit designed to change the response time (e.g., operation mode) of the current limiter. The current limiter may be designed to operate at different selectable speed modes (e.g., slow mode, fast mode) that affect how quickly the current limiter responds to an overcurrent stimulus. The speed modes may be selected by choosing between different current mirror arrangements in the gain adjustment circuit. Regardless of which mode of operation is selected for the current limiter, a speedup circuit may also be implemented, which includes a switch to initiate a nonlinear speedup of the response time after a certain overcurrent stimulus is received.

### TECHNICAL FIELD

This description relates to overcurrent protection in circuits, and more particularly, to a current limiter circuit having a tunable response time.

### BACKGROUND

The protection against voltage drops on a given power rail is a concern, for example, when that power rail is connected to a load via an external port, or some other means. In some situations, current limit circuits are used to prevent the potential on the power rail from browning out when a faulty load is applied. The response time of the current limit circuit is usually very fast in order to limit the amount of supply droop during, for example, a hard-fault condition. However, current limit circuits that are too fast are unable to regain normal operation after certain transient soft-fault conditions or other transient events that may cause output current to rise above the current limit value. To these ends, a number of non-trivial issues remain with developing current limiter circuits.

### SUMMARY

A current limiter is described that includes a gain adjustment circuit designed to change the response time (e.g., operation mode) of the current limiter. A given speed mode of the current limiter may be implemented based on the circuit layout of various transistors and different sets of transistors may be selected to choose between different speed modes, according to some embodiments.

One example current limiter includes a gain stage, and a power switch having a control terminal and a current output and configured to control a current at the current output responsive to a signal at the control terminal. The gain stage includes an amplifier having an amplifier output and first and second amplifier inputs with the first amplifier input coupled to the current output, and the second amplifier input coupled to a reference terminal, a first current mirror, a first switch coupled between the first current mirror and the control terminal of the power switch, a second current mirror, and a second switch coupled between the second current mirror and the control terminal of the power switch. The first current mirror is configured to pull down a current from the control terminal of the power switch at a first rate responsive to the first switch being closed, and the second current mirror is configured to pull down a current from the control terminal of the power switch at a second rate responsive to the second switch being closed. The second rate is different from the first rate.

In some embodiments, the current limiter also includes a speed adjustment circuit having at least a resistor and a switch. The resistor is coupled between the control terminal of the power switch and an output of the gain stage, and the switch has a first terminal coupled to the control terminal of the power switch and a second terminal coupled to the output of the current limiter.

In another example, a printed circuit board (PCB) includes a current limiter coupled to a power terminal and having a power output, and a peripheral output port coupled to the power output. The current limiter includes a gain stage and a power switch having a control terminal and a current output coupled to the power output with the power switch being configured to control a current applied to the power output responsive to a signal at the control terminal. The gain stage includes an amplifier having an amplifier output and first and second amplifier inputs with the first amplifier input coupled to the current output, and the second amplifier input coupled to a reference terminal, a first current mirror, a first switch coupled between the first current mirror and the control terminal of the power switch, a second current mirror, and a second switch coupled between the second current mirror and the control terminal of the power switch. The first current mirror is configured to pull down a current from the control terminal of the power switch at a first rate responsive to the first switch being closed, and the second current mirror is configured to pull down a current from the control terminal of the power switch at a second rate responsive to the second switch being closed. The second rate is different from the first rate.

In another example, a circuit includes a power switch, an amplifier, a first field effect transistor (FET) and a second field effect transistor (FET) having a first current mirror arrangement, and a third field effect transistor (FET) and a fourth field effect transistor (FET) having a second current mirror arrangement. The power switch has a first terminal or node, a second terminal or node, and a control terminal. The amplifier has an output and first and second inputs with the first input coupled to the first terminal of the power switch, and the second input coupled to a reference voltage terminal A first terminal of the first FET is coupled to the output of the amplifier via a first switch, and a first terminal of the second FET is coupled to a current mirror output. A first terminal of the third FET is coupled to the output of the amplifier via a second switch, and a first terminal of the fourth FET is coupled to the current mirror output. A W/L ratio between the first FET and the second FET is different than a W/L ratio between the third FET and the fourth FET.

### BRIEF DESCRIPTION OF THE DRAWINGS

FIG. 1 is a block diagram of an electrical device or system that includes a current limiter, in an example.

FIG. 2 is a block diagram of a current limiter, in an example.

FIG. 3 is a schematic diagram of the current limiter of FIG. 2, in an example.

FIG. 4A is a schematic diagram of a portion of the current limiter of FIG. 2, in an example.

FIG. 4B is a block diagram of a portion of the current limiter of FIG. 2, in another example.

FIG. 5 is a graph showing different gain bandwidth (GBW) products for different operation modes of a current limiter, in an example.

FIG. 6 is a graph showing the response time for various operation modes for a current limiter having a nonlinear speedup response, in an example.

### DETAILED DESCRIPTION

A current limiter is described that includes a gain adjustment circuit designed to change the response time (e.g., operation mode) of the current limiter. In some embodiments, the current limiter also includes a speedup circuit designed to cause a relatively quick reduction of the rail current regardless of the operation mode of the current limiter. According to some embodiments, the current limiter may be designed to operate at different speed modes that affect how quickly the current limiter responds to an overcurrent stimulus. For instance, in a slow mode, the current limiter may have a slower response time for lower overcurrent stimulus to withstand transients that may occur. In a fast mode, the current limiter may react quickly even to low overcurrent stimulus to pull down the rail current. Regardless of which mode of operation is selected for the current limiter, the speedup circuit may include a switch to initiate a nonlinear speedup of the response time after a certain overcurrent stimulus is received. A given speed mode may be implemented based on the circuit layout of various transistors (e.g., based on transistor sizing, as further described below), and different sets of transistors may be selected to choose between different speed modes, according to some embodiments.

General Overview

As described above, a number of non-trivial issues are associated with developing a current limiter. For instance, the response time of a current limiter circuit to different overcurrent stimulus (e.g., the rail current amplitude above a reference current amplitude) dictates how quickly the circuit can prevent a high rail current from damaging a connected load, or the ability for the current limiter to not react too quickly to transient changes of the rail current. Current limiter circuits are designed to either operate in one mode or another. For example, a current limiter circuit may be designed to react very quickly to any overcurrent stimulus, which may provide a high level of safety, but is more vulnerable to unnecessarily browning out the rail current. In contrast, a current limiter designed to react more slowly may be capable of withstanding transient situations that do not require pulling down the rail current, but is more vulnerable to current spikes damaging the load or power source.

Thus, a current limiter that can operate in any one of a number of different response modes is described herein. In an example, one or more power switches (e.g., power field effect transistors or FETs) may be used to regulate the rail current, while an amplifier is used to compare the rail current to a reference current. If the rail current rises above the reference current, an output of the amplifier activates a current mirror to produce a current that assists in pulling down the rail current. According to some embodiments, the size ratio between the FETs of the current mirror determine the operating mode of the current limiter (e.g., whether it responds quickly or slowly to overcurrent stimulus). In some examples, different sets of FETs can be used to form various current mirrors (e.g., a first set of FETs can be for fast operating mode, and a second set of FETs can be used for slow operating mode, and a third set of FETs can be used for an intermediate operating mode). According to some such embodiments, one of the current mirrors can be selected to choose the operating mode of the current limiter.

In some embodiments, the current limiter includes a speedup circuit that can provide a quick increase to the circuit response time even when the current limiter is operating in a slower mode. An output of the gain stage, which includes the various current mirrors, is coupled to the speedup circuit, which includes a resistor in a current path between the gain stage output and the one or more power switches to allow for a selected one of the current mirrors to pull down the control terminal of the power switch and thus regulate the rail current. According to some embodiments, the speedup circuit also includes a speedup switch coupled to the rail. The speedup switch can activate if a high enough overcurrent stimulus exists. Activating the speedup switch provides a path for the selected current mirror to very quickly limit the rail current. According to some embodiments, the speedup circuit maintains circuit protection against large overcurrent transients while allowing slower operating modes to withstand transients. Although embodiments herein are described with reference to a current limiter for regulating rail current, such embodiments may also be useful in any electronic device that uses any type of current regulation.

Electronic Device or System

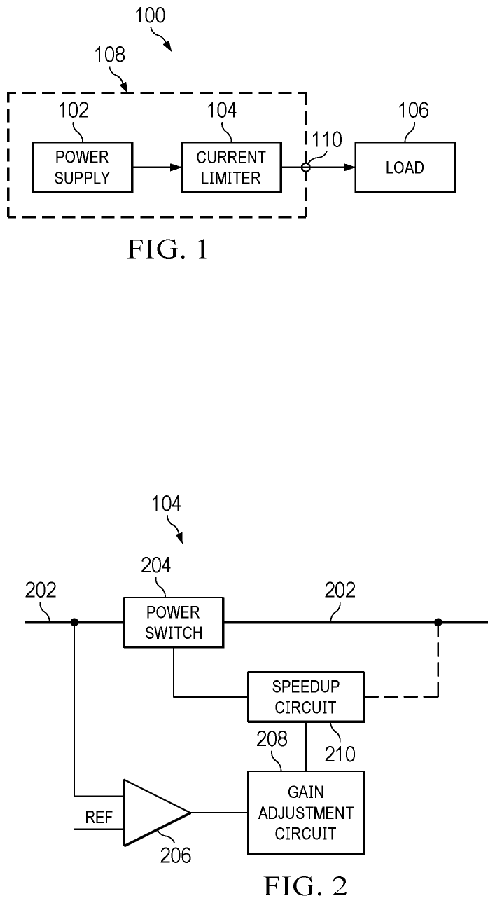

FIG. 1 illustrates at least a portion of an example electronic device or system 100 having a power supply 102 and a current limiter 104. In some embodiments, a load 106 (or a load circuit) is a part of electronic device or system 100 or is coupled to electronic device or system 100. In some cases, electronic device or system 100 is implemented as a system-on-chip, or a chip set populated on a printed circuit board (PCB) which may in turn be populated into a chassis of a multi-chassis system or an otherwise higher-level system, although any number of implementations can be used.

Power supply 102 may represent any type or number of current and/or voltage generators. In some embodiments, power supply 102 generates rail voltage (e.g., VDD, VCC, or HVDD) for supplying power to any number of integrated circuits. The current supplied may be regulated by current limiter 104, according to some embodiments. As further described below, current limiter 104 may be designed to operate in any number of different speed modes (with respect to current limit response time) to limit the rail current if it rises above a threshold, and to limit the rail current very quickly if it rises above a higher threshold. In this manner, the current limiter circuit can have a tunable, nonlinear response time. Current limiter 104 may be provided to protect load 106, power supply 102, and/or any other circuits connected to power supply 102 from receiving dangerously high or otherwise excessive rail currents.

According to some embodiments, power supply 102 and current limiter 104 may be provided together on a PCB 108. In the illustrated example, load 106 is coupled to PCB 108 via an output port 110 to receive power and possibly other data signals from various devices on PCB 108. Output port 110 may be dedicated output voltage port, or any other port that may pass output voltage to a peripheral device, such as a serial port, parallel port, USB port, or HDMI port, to name a few examples, and is coupled to the output power line or terminal (or more broadly the power output) of current limiter 104. In some other examples, load 106 is included on PCB 108. Load 106 may represent another circuit or another device that receives at least rail power that has passed through current limiter 104.

Current Limiter Design

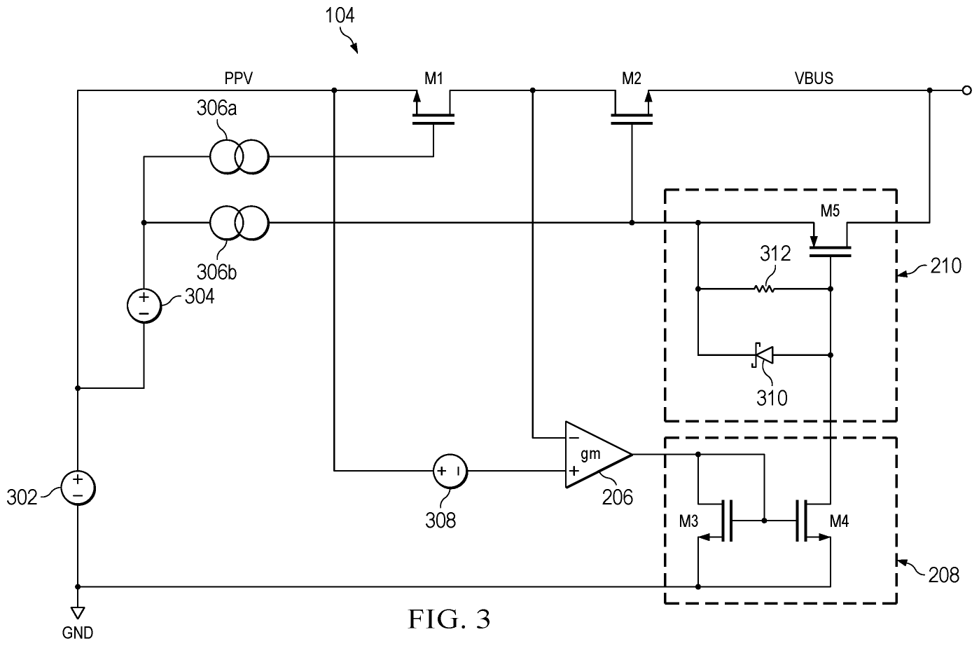

FIG. 2 illustrates a more detailed diagram of current limiter 104, according to some embodiments. A conductive power rail 202 carries a current from power supply 102 to load 106. The power rail 202 is shown as a straight conductive run (e.g., copper or other suitable metal conductor) in this example, but it can have any number of configurations that are capable of carrying current from power supply 102 to load 106. The current on power rail 202 may be regulated via power switch 204 in concert with an amplifier 206, a gain adjustment circuit 208 and a speedup circuit 210. The current regulation may involve reducing the current on power rail 202 if that current rises above a given threshold and pulling the current amplitude down strongly if it rises significantly above the given threshold (or above a second, higher threshold). Such a staggered or staged overcurrent threshold technique is useful to distinguish between a temporary or relatively transient overcurrent condition that can be safely tolerated without causing any damage to the overall system, and a more serious failure-mode based overcurrent condition that calls for a fast current limiting response time.

Power switch 204 may represent any number of switches along rail 202. In some embodiments, power switch 204 includes a power FET with the rail current configured to run through the source and drain of the power FET.

The rail current on rail 202 is sampled at a first input of an amplifier 206, where it can be compared with a reference current (REF) received at a second input of amplifier 206. The reference current (REF) may be, for example, predetermined based on the given application or type of load 106. A low reference current (REF) causes current limiter 104 to react to overcurrents beyond a low reference threshold while a higher reference current (REF) causes current limiter 104 to react to overcurrents beyond a higher threshold. In some examples, the reference current (REF) is fixed, while in other example the reference current (REF) is adjustable by a user, or by an automatic process that dynamically determines an appropriate reference current. Amplifier 206 may include one or more operational amplifiers arranged as a transconductance amplifier with gain gm (e.g., voltage inputs with a current output). Any number of amplifier and/or comparator circuits capable of comparing a current or voltage to a given threshold current or voltage can be used.

According to some embodiments, the output of amplifier 206 is coupled to gain adjustment circuit 208. One or more current mirrors may be used within gain adjustment circuit 208 to reduce the current by a given ratio determined by a size difference between FETs of the one or more current mirrors. According to some embodiments, one current mirror is selected from multiple current mirrors within gain adjustment circuit 208. The operational mode of current limiter 104 (e.g., fast mode, slow mode, or any intermediate mode) may be determined based on which current mirror is selected. According to some embodiments, each current mirror includes a different gain adjusting factor (e.g., current ratio) based on the size difference between the FETs used in the current mirror. One example gain adjustment circuit 208 includes a first current mirror for fast mode and a second current mirror for slow mode. In one such case, gain adjustment circuit 208 includes a third current mirror for an intermediate mode (having a response time between the fast and slow modes).

According to some embodiments, a speedup circuit 210 is coupled to an output of gain adjustment circuit 208. Speedup circuit 210 may be configured to control the process of pulling down the current from a gate (or, more broadly, a control terminal) of power switch 204 (e.g., using the mirrored current from gain adjustment circuit 208), to ultimately reduce the rail current. In some examples, the rail current may be brought down below the REF current to dynamically deactivate gain adjustment circuit 208. The speed in which this occurs may be affected by the size ratio between the FETs in the selected current mirror of gain adjustment circuit 208.

According to some embodiments, speedup circuit 210 includes a speedup switch that is designed to activate if the pulldown current from gain adjustment circuit 208 is too large (e.g., above a second threshold higher than REF). According to some examples, activation of the speedup switch opens a path directly to rail 202, allowing power switch 204 to disable quickly and causing the rail current to be very quickly pulled down to a low level. The speedup switch may be implemented, for example, using a single FET or as its own circuit having any number of FETs.

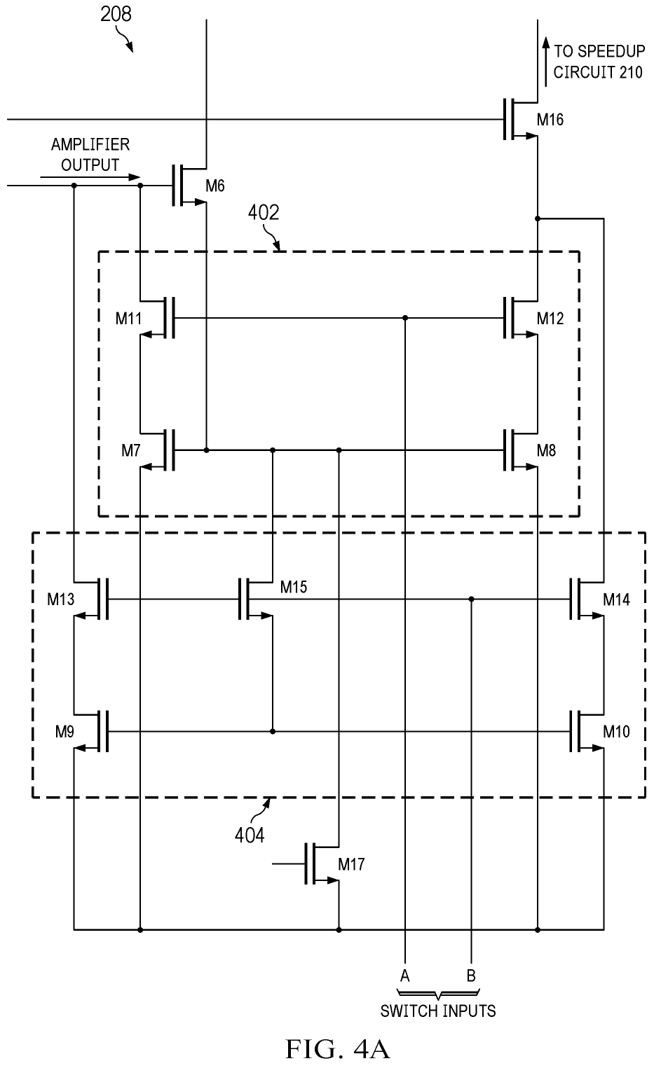

FIG. 3 illustrates an example circuit diagram of current limiter 104. Other elements beyond those illustrated in FIG. 3 could be included as part of current limiter 104, such as various buffers, resistors, and/or capacitors. Also, any of the illustrated elements may be implemented in a variety of different ways that achieves a similar output or function.

According to some embodiments, a first voltage source 302 provides a rail voltage and associated current on the power rail PPV. For some example applications, PPV is set to a voltage amplitude of around 5 volts, although any voltage can be used, including low, medium and high voltages. One or more power switches, such as power FETs M1 and M2, are provided on the rail and regulate the rail current that is ultimately output on VBUS (and may be connected to load 106). A second voltage source 304 may be provided along with any number of charge pumps, such as charge pumps 306a and 306b, to bias the gates of power FETs M1 and M2 and activate each of power FETs M1 and M2. In some examples, an equal number of charge pumps 306a and 306b are provided for an equal number of power switches (e.g., one change pump coupled to the gate of one power switch). In some embodiments, power FET M1 may be replaced by any current sensing element, such as a resistor.

As further described below, the gate potential of power FET M2 may be modulated or otherwise affected by gain adjustment circuit 208 and speedup circuit 210, thus regulating the rail current on VBUS. In some embodiments, the rail current is sampled at a location between one or more power switches on the rail (such as between power FETs M1 and M2) and is fed to a first input of amplifier 208. A reference source 308 may be used to generate a reference current (or a threshold current) that is fed to a second input of amplifier 206. As described above, reference source 308 may be a fixed source to provide a fixed reference current at a reference terminal, or it may be dynamically configurable.

According to some embodiments, the output of amplifier 206 is fed to gain adjustment circuit 208. For example, the output of amplifier 206 may be received by a selected current mirror from among multiple current mirrors. The illustrated example uses a single current mirror for clarity, but the description equally extends to any number of other current mirrors. Responsive to the rail current being less than (or equal to) the reference current, the output of amplifier 206 does not enable FETs M3 and M4 that form a given current mirror arrangement within gain adjustment circuit 208. However, responsive to the rail current rising above the reference current, a current output from amplifier 206 is provided that is proportional to the difference between the rail current and the reference current (multiplied by a gain factor, gm). The difference between the rail current and the reference current may be referred to herein as the overcurrent stimulus or more simply the overcurrent.

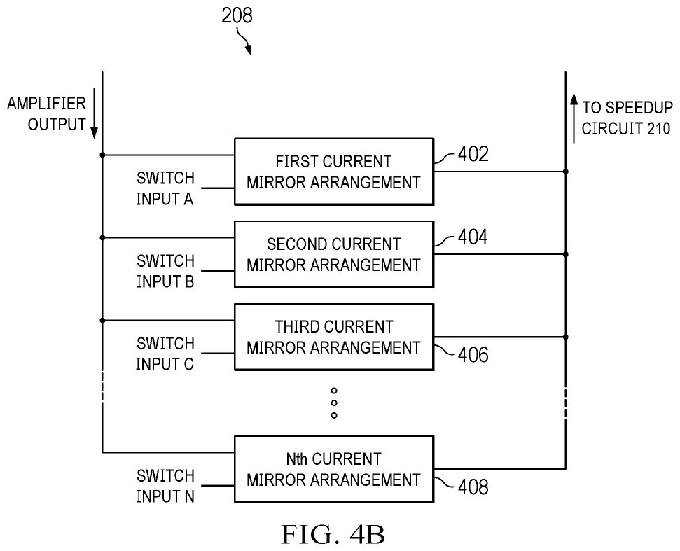

According to some embodiments, FETs M3 and M4 have a current mirror arrangement in which the gates of FETs M3 and M4 are coupled together, the source nodes of FETs M3 and M4 are coupled together, and the drain node of FET M3 is coupled to the gates of both FETs M3 and M4. The ratio of the drain current through FET M3 and the drain current through FET M4 is proportional to the ratio of the sizes (e.g., width/length ratio of semiconductor channel) of FETs M3 and M4. Thus, according to some embodiments, the amount of gain adjusting that occurs within gain adjustment circuit 208 depends on the size ratio between FETs M3 and M4. A relatively large difference in the size ratio (e.g., W/L of M4 over W/L of M3) yields a larger drain current through FET M4 and a faster pull down of the rail current (e.g., fast mode). In contrast, a relatively small or zero difference in the size ratio (e.g., W/L of M4 over W/L of M3) yields a smaller drain current through FET M4 and a slower pull down of the rail current (e.g., slow mode). With only a single current mirror arrangement, current limiter 104 only operates in one mode (e.g., slow mode, fast mode, or some intermediate mode). However, according to some embodiments and as described in more detail with reference to FIGS. 4A and 4B, a particular current mirror can be selected from among more than one current mirror within gain adjustment circuit 208 to choose between different speed modes.

Regardless of what mode current limiter 104 operates in, the current through FET M4 also passes through speedup circuit 210, according to some embodiments. Speedup circuit 210 includes a speedup switch M5 and one or more other elements coupled between a gate of speed switch M5 and a source terminal or node of speedup switch M5. In this example, speedup switch M5 is implemented as a p-channel FET. According to some embodiments, speedup circuit 210 includes a diode 310 coupled between a gate of speedup switch M5 and a gate of power switch M2 (which in this example is the same node as the source node of speedup switch M5). Diode 310 may be used to provide circuit protection in case of very high currents being drawn through mirror FET M4, and could be optional in some implementations. According to some embodiments, speedup circuit 210 includes a resistor 312 coupled between a gate of speedup switch M5 and a gate of power FET M2. Resistor 312 provides a dissipating element across a current path between the gate of power FET M2 and the drain node of mirror FET M4 (part of the current mirror). Accordingly, the current generated across mirror FET M4 pulls down the gate of power FET M2 to regulate the rail current on VBUS. In some examples, a feedback loop is created to regulate the rail current on VBUS by counterbalancing the current through resistor 312 with the current being fed from charge pump 306b.

According to some embodiments, speedup switch M5 is coupled to VBUS. For example, a drain node of speedup switch M5 may be coupled to VBUS to provide a current pull-down path that bypasses power FET M2 when speedup switch M5 is activated. According to some embodiments, speedup switch M5 is activated when the overcurrent stimulus is high enough and the pull-down current through mirror FET M4 correspondingly pulls down the gate of speedup switch M5 enough to activate speedup switch M5. For example, responsive to the product of the pull-down current (I_{PD}) through mirror FET M4 and the resistance of resistor 312 (R₃₁₂) being equal to or greater than the threshold voltage of speedup switch M5 (V_{T_M5}) (e.g., I_{PD}*R₃₁₂=>V_{T_M5}), speedup switch M5 turns on and quickly discharges the gate to the source. When this occurs, the rail current on VBUS can be very quickly pulled down from the current passing through mirror FET M4 and also through speedup switch M5. In some examples, the overcurrent stimulus that causes activation of speedup switch M5 may be considered a second current threshold (e.g., a rail current amplitude higher than the reference current that causes activation of speedup switch M5). According to some embodiments, speedup switch M5 can be used to cause quick pull down of the rail current regardless of the operating speed of current limiter 104 (e.g., regardless of the size ratio used between FETs M3 and M4). In this way, a slow mode of operation can be used while still having the ability to quickly pull down the current, if needed, via speedup switch M5.

The illustrated FETs may be shown as either n-channel (NFET) or p-channel (PFET) devices, but either n-channel or p-channel devices could be used to perform similar functions with some associated reconfiguration of the circuit layout. Similarly, any identification of a source node of a given transistor could also refer to a drain node, and vice versa, depending on the transistor channel type. Although FET devices are used in these examples, in some embodiments, any number of bipolar junction transistors (BJTs) could be used in place of the FET devices.

As described above, gain adjustment circuit 208 may include more than one current mirror arrangement to allow for multiple operating mode speeds. FIG. 4A illustrates an example circuit diagram of at least a portion of gain adjustment circuit 208 having two different current mirror arrangements, according to some embodiments. The amplifier output is received by a first current mirror arrangement 402 and a second current mirror arrangement 404. Although only two current mirror arrangements are shown, one for a relatively fast or first operation mode and one for a relatively slow or second operation mode, any number of additional current mirrors may be coupled to the amplifier output in a similar fashion (e.g., similar to current mirror arrangement 404), so as to provide one or more intermediate operation modes having response times between the respective response times attributable to the fast and slow operation modes. The current limiter response times between any two current mirror arrangements may be considered different if, for example, the response times differ by at least 10%, at least 15%, at least 20%, or at least 25%. Other examples may have current limiter response times that are closer together, but are still considered meaningfully different (e.g., at least 5% different) for the given application and process. More generally, any number of current limiter response times that are purposefully configured to be different from one another can be used.

According to some embodiments, first current mirror arrangement 402 includes mirror FETs M7 and M8 while second current mirror arrangement 404 includes mirror FETs M9 and M10. As further shown, first current mirror arrangement 402 includes selection FETs M11 and M12 and second current mirror arrangement 404 includes selection FETs M13 and M14. In some embodiments, activation FET M6 provides an activation pathway for the gates of mirror FETs M7 and M8 and activation FET M15 provides an activation pathway for the gates of mirror FETs M9 and M10. A first terminal of mirror FET M7 may be considered to be coupled to the amplifier output via selection FET M11, while a first terminal of mirror FET M9 may be considered to be coupled to the amplifier output via selection FET M13. Also, a first terminal of mirror FET M8 may be considered to be coupled to an output of gain adjustment circuit 208 via selection FET M12, while a first terminal of mirror FET M10 may be considered to be coupled to the output of gain adjustment circuit 208 via selection FET M14.

According to some embodiments, switch inputs (A and B) are used to determine which current mirror arrangement is active at a given time. The number of switch inputs may equal the number of current mirror arrangements in order to individually address each of the current mirror arrangements. According to some embodiments, the switch inputs are used to activate the one or more selection FETs of a given current mirror arrangement. In the illustrated example, switch input A is used to activate the gates of selection FETs M11 and M12 of first current mirror arrangement 402, and switch input B is used to activate the gates of selection FETs M13 and M14 of second current mirror arrangement 404.

Focusing on first current mirror arrangement 402, switch input A may be asserted to activate selection FETs M11 and M12, thus allowing for the current received from the amplifier output to flow through current mirror FET M7. First current mirror arrangement 402 causes a proportional current to flow through current mirror FET M8 based on the size ratio between FETs M7 and M8. The current flowing through FET M8 acts as the pull-down current to reduce the rail current via speedup circuit 210. In some embodiments, the pull-down current through FET M8 also passes through FET M16, which acts as a buffer between the various current mirror arrangements and speedup circuit 210. While the first current mirror arrangement 402 is active, second current mirror arrangement 404 is not active as the gates of selection FETs M13 and M14 are held low by the unasserted switch input B.

Focusing on second current mirror arrangement 404, switch input B may be asserted to activate selection FETs M13 and M14, thus allowing for the current received from the amplifier output to flow through FET M9. In some embodiments, switch input B also activates the gate of activation FET M15 to provide an activation pathway to the gates of FETs M9 and M10. Second current mirror arrangement 404 causes a proportional current to flow through FET M10 based on the size ratio between FETs M9 and M10. The current flowing through FET M10 acts as the pull-down current to reduce the rail current via speedup circuit 210. In some embodiments, the pull-down current through FET M10 also passes through FET M16, which acts as a buffer between the various current mirror arrangements and speedup circuit 210. While the second current mirror arrangement 404 is active, first current mirror arrangement 402 is not active as the gates of selection FETs M11 and M12 are held low by the unasserted switch input A.

According to some embodiments, the size ratio between FETs M7 and M8 is different from the size ratio between FETs M9 and M10 to provide two different speed operation modes. The size ratios between any two current mirror arrangements may be considered different if, for example, the size ratios differ by at least 10%, at least 15%, at least 20%, or at least 25%. Other examples may have current mirror size ratios that are closer together, but are still considered meaningfully different (e.g., at least 5% different) for the given application and process. More generally, any number of current mirror size ratios that are purposefully configured to be different from one another can be used. In an example, the size ratio between FETs M7 and M8 may be chosen to provide a low pull-down current through M8, yielding a relatively slow mode of operation (e.g., slower pull down on the rail current), while the size ratio between FETs M9 and M10 may be chosen to provide a higher pull-down current through FET M10, yielding a relatively fast mode of operation (e.g., faster pull down on the rail current). Any number of different speed modes may be selected by providing an equal number of different current mirror arrangements. A particular current mirror arrangement may then be selected to use from among the different current mirror arrangements via the switch inputs.

The switch inputs can be provided or otherwise set manually by a user in some examples, while in other examples the switch inputs can be provided or otherwise set by a processor programmed or otherwise configured to select response time based on parameters of a given application and/or input from a user. In some cases, a 3-to-8 line decoder is used to provide the switch input. In one such example case, three input bits can be set to provide a 3-bit input control word at the input of the decoder, thereby providing up to eight distinct decoder outputs each corresponding to a switch input (A, B, C, D, E, F, G, and H), each of which in turn corresponds to a selectable current mirror arrangement (and a corresponding operation mode or response speed). The 3-bit input control word can be set either by a user or a processor (based on user-provided and/or sensed input that indicates an appropriate response time and mode of operation).

FIG. 4B illustrates a block diagram of gain adjustment circuit 208 that has been extrapolated to include one or more additional current mirror arrangements (e.g., up to N total current mirror arrangements) to select between N number of operation modes, according to some embodiments. First current mirror arrangement 402 and second current mirror arrangement 404 receive the amplifier output and have a current output that leads to speedup circuit 210. Switch inputs A and B can be used to select either first current mirror arrangement 402 or second current mirror arrangement 404, respectively. As discussed above, the different current mirror arrangements have mirror FETs with different size ratios, such that selecting a particular current mirror changes the mode of operation for the current limiter (e.g., the speed of the current limiter).

According to some embodiments, a third current mirror arrangement 406 may be implemented by receiving the same amplifier output and having a current output that leads to speedup circuit 210. Third current mirror arrangement 406 may be activated using another switch input (switch input C) in the same fashion as switch inputs A or B are used to activate either the first current mirror arrangement 402 or the second current mirror arrangement 404. According to some embodiments, third current mirror arrangement 406 includes a similar circuit layout to that of second current mirror arrangement 404 shown in FIG. 4A (e.g., third current mirror arrangement 406 includes at least a set of selection FETs in series with a set of mirror FETs with switch input C controlling the gates of the selection FETs). As discussed above, any number of circuit mirror arrangements can be provided in parallel with one another up to an Nth current mirror arrangement 408 using a corresponding number of N switch inputs to activate a particular circuit mirror. Each of the N current mirror arrangements include a corresponding set of selection FETs and mirror FETs arranged as shown for second current mirror arrangement 404 in FIG. 4A, having an input coupled to the amplifier output and an output that leads to speedup circuit 210.

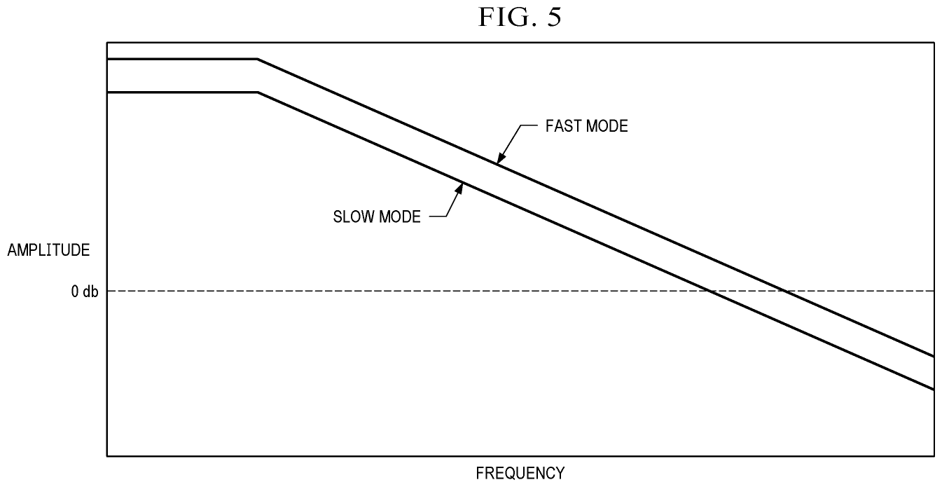

FIG. 5 shows a graph with the frequency response for both a slow mode and fast mode of operation of a current limiter, according to some embodiments. As observed via the crossing at 0 decibels (unity gain), the faster operation mode has a higher gain bandwidth (GBW) which translates to a faster response time of the current limiter compared to the slower operation mode. Although only two operation modes are illustrated here, any number of operation modes may be selected within a given current limiter based on the corresponding number of different current mirror arrangements.

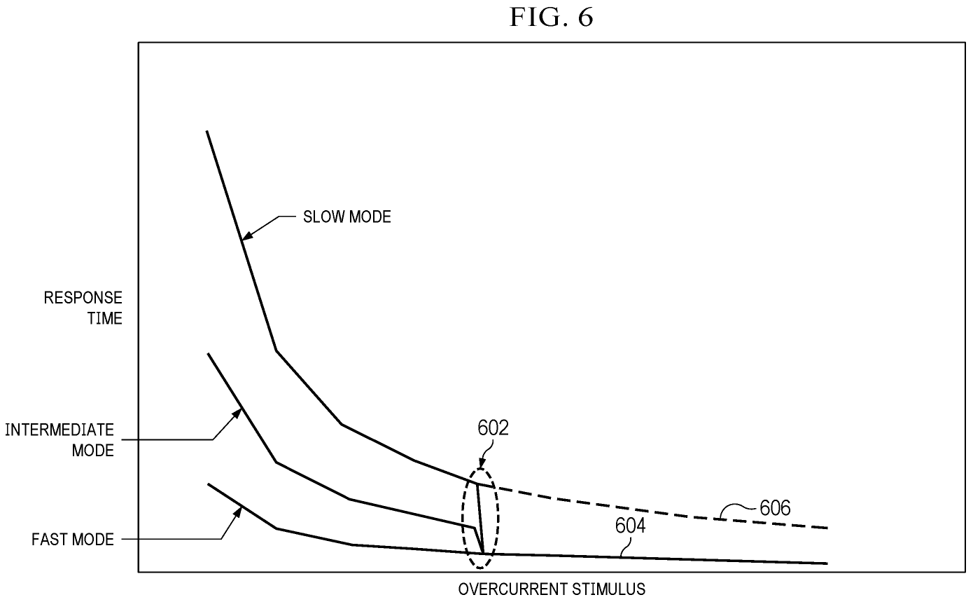

FIG. 6 shows a graph that provides the response time of the current limiter vs. the overcurrent stimulus for different speed operation modes, according to some embodiments. For example, a relatively slow mode of operation (e.g., using a current mirror arrangement having a relatively small difference in the size ratio between FET M4 over FET M3) yields a relatively slow response time for low overcurrent stimulus, while a relatively fast mode of operation (e.g., using a current mirror arrangement having a relatively large difference between the size ratio between FET M4 over M3) yields a relatively fast response time even for low overcurrent stimulus.

According to some embodiments, at a given overcurrent stimulus threshold identified as speedup point 602, the current becomes large enough (e.g., I_{PD}*R₃₁₂=>V_{T_M5}) to activate speedup switch M5 of the speedup circuit 210, and the response time drastically (e.g., 80% or more reduction) decreases across all operation modes. For all higher overcurrent stimulus identified as region 604, a very fast response time is observed regardless of the operation mode used. Region 606 is provided as a dashed line to illustrate what the response time for the slow mode of operation would have otherwise been without speedup circuit 210. Thus, the implementation of speedup circuit 210 allows for slower operation modes to withstand transient changes to the rail current while still clamping down quickly on the rail current for high overcurrent stimulus.

Table 1 below provides actual response times in both a fast mode and a slow mode for various overcurrent amounts when using a current limiter with the aforementioned speed adjustment circuit implemented on a silicon chip, according to an example. The measured response times track closely with the simulated results provided in FIG. 6.

TABLE 1
Circuit Response Times for Different Overcurrent Stimulus

| | Fast Mode | Slow Mode |
|---|---|---|
| Overcurrent (A) | Response Time (μs) | Response Time (μs) |
| 0.50 | 26.4 | 1090 |
| 1.00 | 3.43 | 422 |
| 2.00 | 2.29 | 19.6 |
| 5.00 | 2.27 | 2.69 |

As shown in Table 1, at low overcurrent stimulus (e.g., 2A or less), the current limiter operating in the fast mode shows a much quicker response time compared to operation in the slow mode. However, after the overcurrent stimulus becomes higher (e.g., 5A or more), the response times of both the fast and slow modes is about the same. Furthermore, the response time of the current limiter in the slow mode of operation becomes much quicker at high overcurrent stimulus compared to the response times at lower overcurrent stimulus.

### Further Examples

Example 1 is a current limiter that includes a gain stage, and a power switch having a control terminal and a current output and configured to control a current at the current output responsive to a signal at the control terminal. The gain stage includes an amplifier having an amplifier output and first and second amplifier inputs with the first amplifier input coupled to the current output, and the second amplifier input coupled to a reference terminal, a first current mirror, a first switch coupled between the first current mirror and the control terminal of the power switch, a second current mirror, and a second switch coupled between the second current mirror and the control terminal of the power switch. The first current mirror is configured to pull down a current from the control terminal of the power switch at a first rate responsive to the first switch being closed, and the second current mirror is configured to pull down a current from the control terminal of the power switch at a second rate responsive to the second switch being closed. The second rate is different from the first rate.
Example 2 includes the current limiter of Example 1, wherein the power switch comprises a power field effect transistor (FET).
Example 3 includes the current limiter of Example 1 or 2, wherein the amplifier comprises a transconductance amplifier configured to receive a first voltage at the first amplifier input, and a second voltage at the second amplifier input. The first voltage represents the current output, and the second voltage represents a voltage at the reference terminal.
Example 4 includes the current limiter of Example 3, wherein the reference terminal is a voltage terminal, and the second voltage is based on an amplitude of a voltage at the voltage terminal.
Example 5 includes the current limiter of any one of Examples 1-4, wherein the gain stage has an output, and the current limiter further comprises a speed adjustment circuit coupled to the output of the gain stage.
Example 6 includes the current limiter of Example 5, wherein the speed adjustment circuit comprises a resistor coupled between the control terminal of the power switch and the output of the gain stage, and a switch having a first terminal coupled to the control terminal of the power switch and a second terminal coupled to the current output.
Example 7 includes the current limiter of Example 6, wherein the speed adjustment circuit further comprises a diode coupled between the control terminal of the power switch and the output of the gain stage.
Example 8 includes the current limiter of Example 6 or 7, wherein the switch comprises a field effect transistor (FET) having a control terminal coupled to the output of the gain stage.
Example 9 includes the current limiter of any one of Examples 1-8, wherein the gain stage further comprises a third switch coupled to the amplifier output, and a third current mirror coupled to the third switch. The third current mirror is configured to pull down a current from the control terminal of the power switch at a third rate responsive to the third switch being closed. The third rate is different from the first rate and the second rate.
Example 10 includes the current limiter of any one of Examples 1-9, wherein the power switch is a first power switch and the current limiter further comprises a second power switch that shares a terminal with the first power switch.
Example 11 is a printed circuit board (PCB) that includes a current limiter coupled to a power terminal and having a power output, and a peripheral output port coupled to the power output. The current limiter includes a gain stage and a power switch having a control terminal and a current output coupled to the power output with the power switch being configured to control a current applied to the power output responsive to a signal at the control terminal. The gain stage includes an amplifier having an amplifier output and first and second amplifier inputs with the first amplifier input coupled to the current output, and the second amplifier input coupled to a reference terminal, a first current mirror, a first switch coupled between the first current mirror and the control terminal of the power switch, a second current mirror, and a second switch coupled between the second current mirror and the control terminal of the power switch. The first current mirror is configured to pull down a current from the control terminal of the power switch at a first rate responsive to the first switch being closed, and the second current mirror is configured to pull down a current from the control terminal of the power switch at a second rate responsive to the second switch being closed. The second rate is different from the first rate.
Example 12 includes the PCB of Example 11, wherein the power switch comprises a power field effect transistor (FET).
Example 13 includes the PCB of Example 11 or 12, wherein the amplifier comprises a transconductance amplifier configured to receive a first voltage at the first amplifier input, and a second voltage at the second amplifier input. The first voltage represents the current output, and the second voltage represents a voltage at the reference terminal.
Example 14 includes the PCB of Example 13, wherein the reference terminal is a voltage terminal, and the second voltage is based on an amplitude of a voltage at the voltage terminal.
Example 15 includes the PCB of any one of Examples 11-14, wherein the gain stage has an output, and the PCB further comprises a speed adjustment circuit coupled to the output of the gain stage.
Example 16 includes the PCB of Example 15, wherein the speed adjustment circuit includes a resistor coupled between the control terminal of the power switch and the output of the gain stage, and a switch having a first terminal coupled to the control terminal of the power switch and a second terminal coupled to the power output.
Example 17 includes the PCB of Example 16, wherein the speed adjustment circuit further comprises a diode coupled between the control terminal of the power switch and the output of the gain stage.
Example 18 includes the PCB of Example 16 or 17, wherein the switch comprises a field effect transistor (FET) having a control terminal coupled to the output of the gain stage.
Example 19 includes the PCB of any one of Examples 11-18, wherein the gain stage further comprises a third switch coupled to the amplifier output, and a third current mirror coupled to the third switch. The third current mirror is configured to pull down a current from the control terminal of the power switch at a third rate responsive to the third switch being closed. The third rate is different from the first rate and the second rate.
Example 20 includes the PCB of any one of Examples 11-19, wherein the power switch is a first power switch and the current limiter further comprises a second power switch that shares a terminal with the first power switch.
Example 21 is a circuit that includes a power switch having a first terminal, a second terminal, and a control terminal; an amplifier having an output and first and second inputs with the first input coupled to the first terminal of the power switch, and the second input coupled to a reference voltage terminal; a first field effect transistor (FET) and a second field effect transistor (FET) having a first current mirror arrangement; and a third field effect transistor (FET) and a fourth field effect transistor (FET) having a second current mirror arrangement. A first terminal of the first FET is coupled to the output of the amplifier via a first switch, and a first terminal of the second FET is coupled to a current mirror output. A first terminal of the third FET is coupled to the output of the amplifier via a second switch, and a first terminal of the fourth FET is coupled to the current mirror output. A width/length (W/L) ratio between the first FET and the second FET is different than a W/L ratio between the third FET and the fourth FET.
Example 22 includes the circuit of Example 21, wherein the power switch comprises a power field effect transistor (FET).
Example 23 includes the circuit of Example 21 or 22, wherein the amplifier is a transconductance amplifier.
Example 24 includes the circuit of any one of Examples 21-23, wherein a control terminal of the first FET is coupled to a control terminal of the second FET, and a second terminal of the first FET is coupled to a second terminal of the second FET.
Example 25 includes the circuit of any one of Examples 21-24, wherein a control terminal of the third FET is coupled to a control terminal of the fourth FET, and a second terminal of the third FET is coupled to a second terminal of the fourth FET.
Example 26 includes the circuit of any one of Examples 21-25, further comprising a diode coupled between the control terminal of the power switch and the current mirror output.
Example 27 includes the circuit of any one of Examples 21-26, further comprising a resistor coupled between the control terminal of the power switch and the current mirror output.
Example 28 includes the circuit of Example 27, further comprising an additional field effect transistor (FET) having a first terminal coupled to the control terminal of the power switch, a second terminal coupled to the second terminal of the power switch, and a control terminal coupled to the current mirror output.
Example 29 includes the circuit of any one of Examples 21-28, further comprising a fifth field effect transistor (FET) and a sixth field effect transistor (FET) having a third current mirror arrangement, wherein a first terminal of the fifth FET is coupled to the output of the amplifier via a third switch, and wherein a first terminal of the sixth FET is coupled to the current mirror output.
Example 30 includes the circuit of any one of Examples 21-29, wherein the power switch is a first power switch and the circuit further comprises a second power switch that shares a terminal with the first power switch.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end user and/or a third party.

While the use of particular transistors is described herein, other transistors (or equivalent devices) may be used instead. For example, a p-channel field effect transistor (PFET) may be used in place of an n-channel field effect transistor (NFET) with little or no changes to the circuit. Furthermore, other types of transistors may be used (such as bipolar junction transistors (BJTs)). Furthermore, the devices may be implemented in/over a silicon substrate (Si), a silicon carbide substrate (SiC), a gallium nitride substrate (GaN) or a gallium arsenide substrate (GaAs). Moreover, reference to transistor features such as gate, source, or drain is not intended to exclude any suitable transistor technologies. For instance, features such as source, drain, and gate are typically used to refer to a FET, while emitter, collector, and base are typically used to refer to a BJT. Such features may be used interchangeably herein. For instance, reference to the gate of a transistor may refer to either the gate of a FET or the base of a BJT, and vice-versa. In some examples, a control terminal may refer to either the gate of a FET or the base of a BJT. Any other suitable transistor technologies can be used. Any such transistors can be used as a switch, with the gate or base or other comparable feature acting as a switch select input that can be driven to connect the source and drain (or the emitter and collector, as the case may be).

References herein to a field effect transistor (FET) being “ON” (or a switch being closed) means that the conduction channel of the FET is present, and drain current may flow through the FET. References herein to a FET being “OFF” (or a switch being open) means that the conduction channel is not present, and drain current does not flow through the FET. A FET that is OFF, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described examples, and other examples are possible within the scope of the claims.

What is claimed is:

1. A current limiter, comprising:
a power switch having a control terminal and a current output, the power switch configured to control a current at the current output responsive to a signal at the control terminal; and
a gain stage comprising:
an amplifier having an amplifier output and first and second amplifier inputs, the first amplifier input coupled to the current output, and the second amplifier input coupled to a reference terminal;
a first current mirror;
a first switch coupled between the first current mirror and the control terminal of the power switch;
a second current mirror; and
a second switch coupled between the second current mirror and the control terminal of the power switch;
wherein the first current mirror is configured to pull down a current from the control terminal of the power switch at a first rate responsive to the first switch being closed, and the second current mirror is configured to pull down a current from the control terminal of the power switch at a second rate responsive to the second switch being closed, the second rate being different from the first rate.

2. The current limiter of claim 1, wherein:
the amplifier comprises a transconductance amplifier configured to receive: a first voltage at the first amplifier input; and a second voltage at the second amplifier input;
the first voltage represents the current output, and the second voltage represents a voltage at the reference terminal.

3. The current limiter of claim 2, wherein the reference terminal is a voltage terminal, and the second voltage is based on an amplitude of a voltage at the voltage terminal.

4. The current limiter of claim 1, wherein the gain stage has an output, and the current limiter further comprises a speed adjustment circuit coupled to the output of the gain stage.

5. The current limiter of claim 4, wherein the speed adjustment circuit comprises:
a resistor coupled between the control terminal of the power switch and the output of the gain stage; and
a switch having a first terminal coupled to the control terminal of the power switch and a second terminal coupled to the current output.

6. The current limiter of claim 5, wherein the speed adjustment circuit further comprises a diode coupled between the control terminal of the power switch and the output of the gain stage.

7. The current limiter of claim 5, wherein the switch comprises a field effect transistor (FET) having a control terminal coupled to the output of the gain stage.

8. The current limiter of claim 1, wherein the gain stage further comprises a third switch coupled to the amplifier output, and a third current mirror coupled to the third switch, wherein the third current mirror is configured to pull down a current from the control terminal of the power switch at a third rate responsive to the third switch being closed, the third rate being different from the first rate and the second rate.

9. A printed circuit board (PCB) comprising:
a current limiter coupled to a power terminal and having a power output; and
a peripheral output port coupled to the power output;
wherein the current limiter further comprises:
a power switch having a control terminal and a current output coupled to the power output, the power switch configured to control a current applied to the power output responsive to a signal at the control terminal; and
a gain stage comprising:
an amplifier having an amplifier output and first and second amplifier inputs, the first amplifier input coupled to the current output, and the second amplifier input coupled to a reference terminal;
a first current mirror;
a first switch coupled between the first current mirror and the control terminal of the power switch;
a second current mirror; and
a second switch coupled between the second current mirror and the control terminal of the power switch;
wherein the first current mirror is configured to pull down a current from the control terminal of the power switch at a first rate responsive to the first switch being closed, and the second current mirror is configured to pull down a current from the control terminal of the power switch at a second rate responsive to the second switch being closed, the second rate being different from the first rate.

10. The PCB of claim 9, wherein:
the amplifier comprises a transconductance amplifier configured to receive: a first voltage at the first amplifier input; and a second voltage at the second amplifier input;
the first voltage represents the current output, and the second voltage represents a voltage at the reference terminal.

11. The PCB of claim 9, wherein the reference terminal is a voltage terminal, and the second voltage is based on an amplitude of a voltage at the voltage terminal.

12. The PCB of claim 9, wherein the gain stage has an output, and the PCB further comprises a speed adjustment circuit coupled to the output of the gain stage.

13. The PCB of claim 12, wherein the speed adjustment circuit comprises:
a resistor coupled between the control terminal of the power switch and the output of the gain stage; and
a switch having a first terminal coupled to the control terminal of the power switch and a second terminal coupled to the power output.

14. The PCB of claim 13, wherein the speed adjustment circuit further comprises a diode coupled between the control terminal of the power switch and the output of the gain stage.

15. The PCB of claim 13, wherein the switch comprises a field effect transistor (FET) having a control terminal coupled to the output of the gain stage.

16. The PCB of claim 9, wherein the gain stage further comprises a third switch coupled to the amplifier output, and a third current mirror coupled to the third switch, wherein the third current mirror is configured to pull down a current from the control terminal of the power switch at a third rate responsive to the third switch being closed, the third rate being different from the first rate and the second rate.

17. A circuit, comprising:
a power switch having a first terminal, a second terminal, and a control terminal;
an amplifier having an output and first and second inputs, the first input coupled to the first terminal of the power switch, and the second input coupled to a reference voltage terminal;
a first field effect transistor (FET) and a second field effect transistor (FET) having a first current mirror arrangement, wherein a first terminal of the first FET is coupled to the output of the amplifier via a first switch, and a first terminal of the second FET is coupled to a current mirror output; and
a third field effect transistor (FET) and a fourth field effect transistor (FET) having a second current mirror arrangement, wherein a first terminal of the third FET is coupled to the output of the amplifier via a second switch, and a first terminal of the fourth FET is coupled to the current mirror output,
wherein a width/length (W/L) ratio between the first FET and the second FET is different than a W/L ratio between the third FET and the fourth FET.

18. The circuit of claim 17, wherein a control terminal of the first FET is coupled to a control terminal of the second FET, a second terminal of the first FET is coupled to a second terminal of the second FET, a control terminal of the third FET is coupled to a control terminal of the fourth FET, and a second terminal of the third FET is coupled to a second terminal of the fourth FET.

19. The circuit of claim 17, further comprising:
a diode coupled between the control terminal of the power switch and the current mirror output;
a resistor coupled between the control terminal of the power switch and the current mirror output; and
an additional field effect transistor (FET) having a first terminal coupled to the control terminal of the power switch, a second terminal coupled to the second terminal of the power switch, and a control terminal coupled to the current mirror output.

20. The circuit of claim 17, further comprising a fifth field effect transistor (FET) and a sixth field effect transistor (FET) having a third current mirror arrangement, wherein a first terminal of the fifth FET is coupled to the output of the amplifier via a third switch, and a first terminal of the sixth FET is coupled to the current mirror output.
